(19) United States
(12) Patent Application Publication
(10) Pub. No.: US 2025/0159827 A1
(43) Pub. Date: May 15, 2025

(54) DISPLAY DEVICE AND MANUFACTURING METHOD THEREOF

(71) Applicant: SAMSUNG DISPLAY CO., LTD., Yongin-si (KR)

(72) Inventors: Daewoo LEE, Yongin-si (KR); Minhee PARK, Yongin-si (KR); Jae Young SIM, Yongin-si (KR); Kyunghoon CHAE, Yongin-si (KR)

(21) Appl. No.: 18/760,158

(22) Filed: Jul. 1, 2024

(30) Foreign Application Priority Data
Nov. 9, 2023 (KR) 10-2023-0154766

(51) Int. Cl. H05K 5/03; H05K 5/02; H05K 7/20

(52) U.S. Cl. CPC H05K 5/03; H05K 5/0247; H05K 7/20963

(57) ABSTRACT

A display device includes a display panel, and a first resin layer and a second resin layer located on a rear surface of the display panel, wherein the first resin layer is overlapping a side surface of the display panel, the second resin layer is overlapping the driving part of the display panel, and the first resin layer and the second resin layer include different materials.

This application claims priority to Korean Patent Application No. 10-2023-0154766, filed on Nov. 9, 2023, and all the benefits accruing therefrom under 35 U.S.C. § 119, the content of which in its entirety is herein incorporated by reference.

### BACKGROUND

### 1. Field

This invention relates to a display device, and more particularly to a display device having improved strength and a method of manufacturing the same.

### 2. Description of the Related Art

Electronic devices such as smart phones, tablets, laptop computers, and smart televisions are being developed.

These electronic devices are equipped with a display device to provide information.

Electronic devices further include various electronic modules in addition to display devices.

The electronic devices may include a display device whose portion is bent to implement a slim bezel.

The bending portion of such a display device may be vulnerable to external shock, and separate reinforcing materials may be required.

### SUMMARY

Embodiments are intended to provide a display device with improved strength and heat dissipation characteristics and a method of manufacturing the same.

In an embodiment, a display device includes a display panel, and a first resin layer and a second resin layer located on a rear surface of the display panel, wherein the first resin layer is overlapping a side surface of the display panel, and the second resin layer is positioned on a rear surface of the display panel, where the second resin layer is overlapping the driving part of the display panel, and the first resin layer and the second resin layer include different materials.

In an embodiment, the first resin layer may have a Young's modulus in the range of about 0.1 MPa to about 1 GPa.

In an embodiment, the first resin layer may include a thermosetting resin or a UV curing resin.

In an embodiment, the first resin layer may include one or more of an acrylic resin, an epoxy resin, a silicone resin, and combinations thereof.

In an embodiment, the display panel may include a bending portion, and the first resin layer may be positioned to overlap the bending portion.

In an embodiment, the second resin layer may include a conductive polymer resin.

In an embodiment, the second resin layer may include a polymer having an electrical conductivity of about 100 S/cm² or more.

In an embodiment, the second resin layer may include one or more of the compounds represented by the following Formulas 1 to 5:

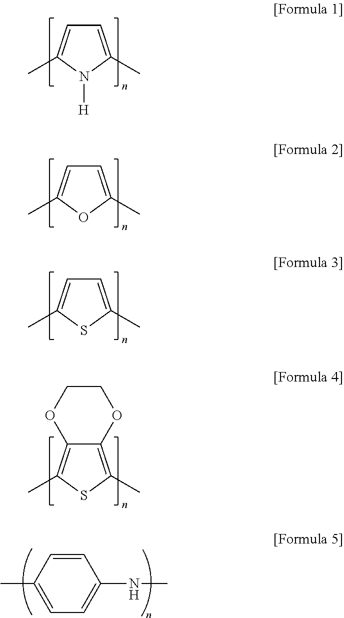

In an embodiment, in Formulas 1 to 5, n may be in the range of about 10 to about 10,000.

In an embodiment, the second resin layer may include a thermally conductive filler.

In an embodiment, the content of the thermally conductive filler may be in the range of about 0.01 vol % to about 95 vol % based on the total volume of the second resin layer.

In an embodiment, the display device may further include a third resin layer overlapping the display panel.

In an embodiment, the third resin layer may include one or more of a thermosetting resin, a UV curing resin, a conductive polymer resin, and combinations thereof.

In an embodiment, the display device may further include a fourth resin layer overlapping the display panel.

In an embodiment, the method of manufacturing a display device includes preparing a mold including a separated first space and a second space, positioning the mold on the back surface of the display panel, and filling the first resin in the first space and filling a second resin, which has different physical properties from the first resin, in the second space, where the first space of the mold is positioned to overlap the side of the display panel, and where the second space of the mold is positioned to overlap the driving part of the display panel.

In an embodiment, the first resin may include a thermosetting resin or a UV curing resin.

In an embodiment, the second resin may include a conductive polymer resin.

In an embodiment, the mold may further include a third space, and the third space of the mold may be overlapping the display panel.

In an embodiment, the method may further include filling the third space of the mold with a third resin, wherein the third resin may include one or more of a thermosetting resin, a UV curing resin, a conductive polymer resin, and a combination thereof.

In an embodiment, the mold includes openings located in a first space and a second space, and in the step of filling the first space with a first resin and filling the second space with a second resin having physical properties different from those of the first resin, the opening may be filled with the first resin and the second resin.

In an embodiment, the method may further include removing the mold, and in the step of removing the mold, the first resin and the second resin filled in the opening may be cut and removed.

According to embodiments, a display device with improved strength and heat dissipation characteristics and a method of manufacturing the same are provided.

### BRIEF DESCRIPTION OF THE DRAWINGS

FIG. 1 shows the back of a display device, according to an embodiment.

FIG. 2 shows a cross-section of the display device of FIG. 1 taken along line I-I′, according to an embodiment.

FIG. 3 shows the same area as FIG. 1, according to another embodiment.

FIG. 4 shows the same area as FIG. 1, according to another embodiment.

FIG. 5 shows the same area as FIG. 1, according to another embodiment.

FIG. 6 shows a mold, according to an embodiment.

FIG. 7 shows the front of the mold of FIG. 6, according to an embodiment.

FIG. 8 illustrates a method of manufacturing a display device, according to an embodiment.

FIG. 9 illustrates a method of manufacturing a display device, according to an embodiment.

FIG. 10 illustrates a method of manufacturing a display device, according to an embodiment.

### DETAILED DESCRIPTION

Hereinafter, with reference to the attached drawings, various embodiments of the invention will be described in detail so that those skilled in the art can easily implement the invention.

The invention may be implemented in many different forms and is not limited to the embodiments described herein.

In order to clearly explain the invention, parts that are not relevant to the description are omitted, and identical or similar components are assigned the same reference numerals throughout the specification.

In addition, the size and thickness of each component shown in the drawings are arbitrarily shown for convenience of explanation, so the invention is not necessarily limited to that which is shown.

In the drawings, the thicknesses are enlarged to clearly express various layers and areas.

And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between.

Conversely, when a part is said to be “right on top” of another part, it means that there is no other part in between.

In addition, being “above” or “on” a reference part means being located above or below the reference part, and does not necessarily mean being located “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in a cross-section,” this means when a cross-section of the target portion is cut vertically and viewed from the side.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise,” and variations such as “comprises” or “comprising,” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the invention.

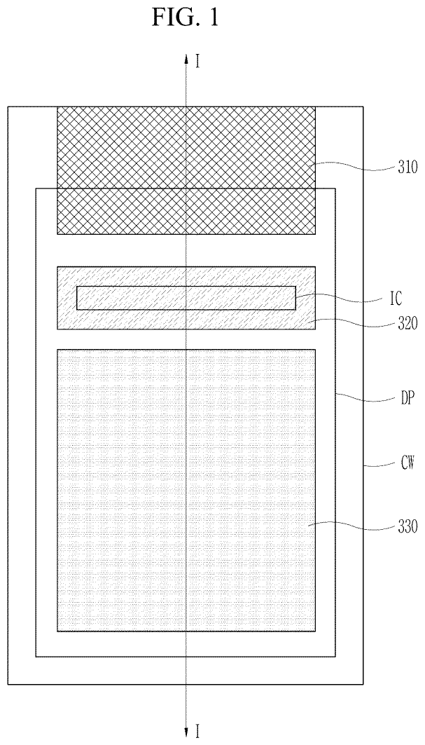

FIG. 1 shows the back of a display device, according to an embodiment.

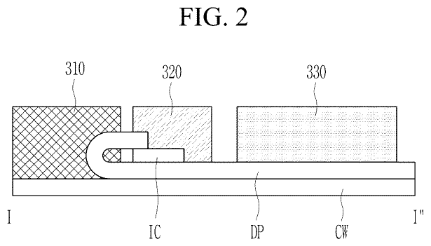

FIG. 2 is a cross-section of the display device of FIG. 1 taken along line I-I of

FIG. 1, according to an embodiment.

In an embodiment and referring to FIG. 1, the display device includes a cover window CW, a display panel DP, and a driver IC.

FIG. 1 shows the back side of the display device, not the display side.

In an embodiment and referring to FIG. 1, the display device includes a first resin layer 310 overlapping with the bending portion of the display panel DP, a second resin layer 320 overlapping with the driver IC, and a third resin layer 330 overlapping with the display panel DP.

As will be explained separately later, the display device according to an embodiment is characterized by satisfying the physical properties required for each area by placing resin layers with different characteristics on the back of the display panel DP.

That is, in an embodiment, the first resin layer 310, the second resin layer 320, and the third resin layer 330 contain different resins and may have different materials and physical properties.

In an embodiment and referring to FIGS. 1 and 2 simultaneously, the first resin layer 310 may cover the bending portion of the display panel DP.

In an embodiment, the bending portion where the display panel DP is bent is vulnerable to cracks.

Therefore, a structure to protect the strength of the bending portion is needed in this area.

Accordingly, in an embodiment, the first resin layer 310 of this embodiment may have a Young's modulus in the range of about 0.1 MPa to about 1 GPa.

In an embodiment, the first resin layer 310 may include a heat-curable resin or a UV-curable resin.

In another embodiment, it may include a dual-cure resin that is cured by both heat and UV.

For example, in an embodiment, the first resin layer 310 may include an acrylic-based resin, an epoxy-based resin, a silicone-based resin, and combinations thereof.

In an embodiment, the acrylic resin may contain monomers, oligomers, and radical photoinitiators, and upon UV irradiation, the photoinitiators may generate radicals to form an acrylic network.

In an embodiment, the epoxy resins may contain monomers, oligomers, cationic photoinitiators, and catalysts. The cationic photoinitiators generate cations upon UV irradiation and may form a network through an epoxy ring opening reaction.

In an embodiment, the silicone-based resins may contain monomers, oligomers, catalysts, and inhibitors, and upon UV irradiation, a ligand bond connected to the catalyst is broken, activating the catalyst, and then a reaction can occur.

In an embodiment, when the first resin layer 310 includes an acrylic resin, acrylic photocuring may be performed first and acrylic heat curing may be performed second.

In an embodiment, the first resin layer 310 may include both an acrylic resin and an epoxy resin.

At this time, in an embodiment, the acrylic resin may include monomers, oligomers, and radical photoinitiators, and the epoxy resin may include monomers, oligomers, anionic photoinitiators, catalysts, and inhibitors.

In this case, in an embodiment, acrylic photocuring may be performed first, and epoxy heat curing may be performed second.

In an embodiment, in the primary curing, upon UV irradiation, the photoinitiator generates radicals to form an acrylic network, and in the secondary curing, the anionic thermal initiator contained in the epoxy resin generates anions in the thermal curing process to form a network through an epoxy ring opening reaction.

In an embodiment, the first resin layer 310 may include both an acrylic resin and a urethane resin.

In an embodiment, the acrylic resin may contain monomers, oligomers, and radical photoinitiators, and the urethane resin may contain isocyanate and a catalyst.

In an embodiment, acrylic light curing may be performed first, and urethane moisture curing may be performed second.

In an embodiment, in primary curing, upon UV irradiation, the photoinitiator generates radicals to form an acrylic network, and in secondary curing, isocyanate may react with OH of moisture in the air to form a urethane network.

In an embodiment, when the first resin layer 310 includes a silicone-based resin, first catalyst activation and second thermal curing processes may be performed.

In an embodiment, in the first catalyst activation process, upon UV irradiation, the ligand bond connected to the catalyst is broken down, activating the catalyst and increasing reactivity, but the reaction may be inhibited by inhibitors.

In an embodiment, afterwards, a catalyst activated in the second thermal curing process increases the reaction rate of hydrogen silylation between silicone resins, thereby forming a silicone network.

In an embodiment and as shown in FIGS. 1 and 2, the first resin layer 310 may be positioned to cover the bending portion of the display panel DP.

In an embodiment, the first resin layer 310 may cover the side surface of the display panel DP.

In an embodiment, the second resin layer 320 may be positioned to overlap the driving unit IC.

In an embodiment, the second resin layer 320 can protect the driving unit, prevent heat generation, and shield electromagnetic waves.

Accordingly, in an embodiment, the second resin layer 320 may include a conductive polymer-based resin having high electrical conductivity.

Specifically, in an embodiment, the second resin layer 320 may include a polymer having electrical conductivity of about 100 S/cm² or more.

In an embodiment, unlike the first resin layer 310 where high strength was required, the second resin layer 320 overlapping the drive unit may contain a different material from the first resin layer 310, as it requires heat generation and electromagnetic shielding functions.

Specifically, in an embodiment, the second resin layer 320 may include a conductive polymer resin whose resin monomer structure exhibits high electrical conductivity after polymerization, such as Pyrrole, Furan, Thiophene, PEDOS, Aniline, Acetylene, and Paraphenylene.

For example, in an embodiment, the second resin layer 320 may include one or more polymers selected from the group consisting of Polypyrrole, Polyfuran, Polythiophene, PEDOS, and Polyaniline, that is, the second resin layer 320 may include one or more polymers represented by the following Formulas 1 to 5.

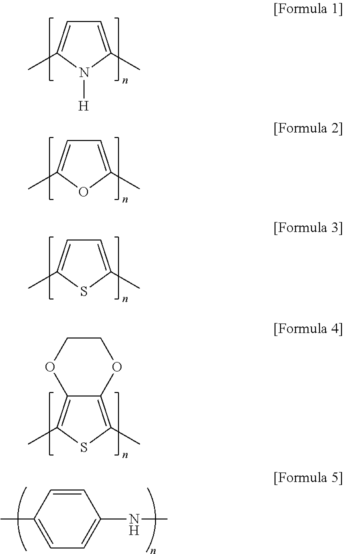

In an embodiment, in Formulas 1 to 5, n may be in the range of about 10 to about 10,000.

In an embodiment, the second resin layer 320 may further include a thermally conductive filler.

In an embodiment, the thermally conductive filler may include metal or conductive particles.

For example, in an embodiment, the thermally conductive filler may include, but is not limited to, Cu or Al.

In an embodiment, the shape of the thermally conductive filler may vary.

For example, in an embodiment, the shape of the thermally conductive filler may be rod-shaped, needle-shaped, or circular.

In an embodiment, heat dissipation characteristics can be improved because additional heat dissipation and radiation paths are secured through the thermally conductive filler.

In an embodiment, the content of the thermally conductive filler may be in the range of about 0.01 vol % to about 95 vol % based on the total volume of the entire second resin layer 320.

If the content of the thermally conductive filler is less than about 0.01 vol %, it may not have sufficient heat dissipation characteristics, and if the content of the thermally conductive filler is more than about 95 vol %, the shape of the second resin layer 320 may not be maintained.

In an embodiment, the third resin layer 330 may be overlapping the display panel DP.

In an embodiment, the third resin layer 330 may be overlapping most areas of the display panel DP and may have heat dissipation and electromagnetic wave shielding functions while absorbing shock applied to the display panel from the rear.

Accordingly, in an embodiment, the third resin layer 330 may include one or more of the material of the first resin layer 310 and the material of the second resin layer 320.

In an embodiment, the third resin layer 330 may include a heat-curable resin or a UV-curable resin.

In another embodiment, the third resin layer 330 may include a dual-cure resin that is cured by both heat and UV.

Additionally, in an embodiment, the third resin layer 330 may include a polymer having electrical conductivity of about 100 S/cm² or more.

That is, in an embodiment, the third resin layer 330 may simultaneously include a heat-curable or UV-curable resin and a conductive polymer resin.

However, this is only an example, and, in an embodiment, the third resin layer may include only a thermosetting or UV-curing resin or only a conductive polymer resin.

In an embodiment and referring to FIG. 1 and FIG. 2, the first resin layer 310, the second resin layer 320, and the third resin layer 330 are all shown, but in other embodiments, the first resin layer 310 and the second resin layer 320 may only be present, it may include only part of the second resin layer 320 and the third resin layer 330, or may further include a fourth resin layer 340 or a fifth resin layer 350.

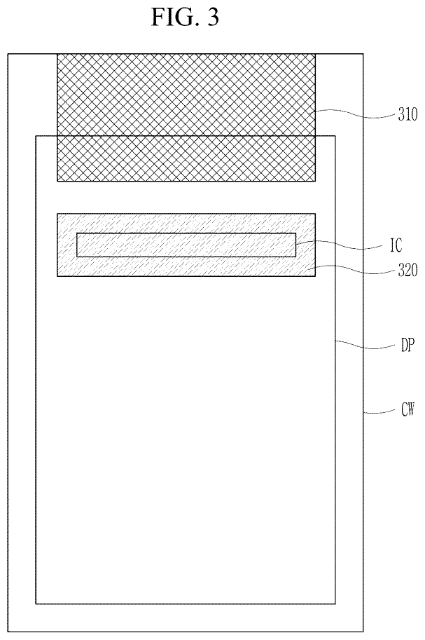

In an embodiment and referring to FIG. 3, the display device includes a first resin layer 310 and a second resin layer 320, and is the same as FIG. 1 except that it does not include a third resin layer 330.

Detailed descriptions of the same components are omitted.

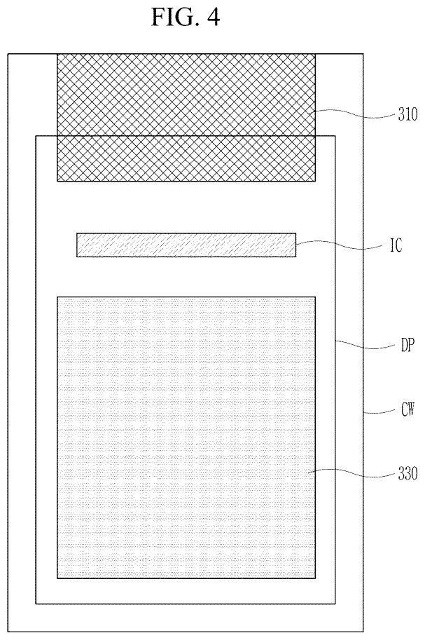

FIG. 4 shows the same area as FIG. 1 for another embodiment.

In an embodiment and referring to FIG. 4, the display device includes a first resin layer 310 and a third resin layer 330, and is the same as FIG. 1 except that it does not include a second resin layer 320.

Detailed descriptions of the same components are omitted.

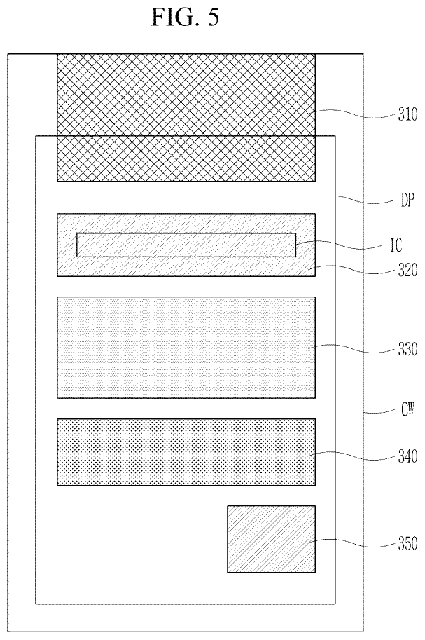

FIG. 5 shows the same area as FIG. 1 for another embodiment.

In an embodiment and referring to FIG. 5, the display device is the same as FIG. 1 except that it further includes a fourth resin layer 340 and a fifth resin layer 350.

Detailed descriptions of the same components are omitted.

In an embodiment and referring to FIG. 5, the display device further includes a fourth resin layer 340 and a fifth resin layer 350.

In an embodiment, physical properties required for each area of the display panel DP may be different, and therefore, a plurality of resin layers with different physical properties may be located on the back of the display panel DP.

Now, the manufacturing method of the display device according to an embodiment will be described below.

In an embodiment, the method of manufacturing a display device includes preparing a mold including a first space and a second space, wherein the first space and second space are separated from each other, placing the mold on the back of the display panel, and applying a first resin to the first space and filling the second space with a second resin, wherein the second resin has different physical properties from the first resin.

At this time, in an embodiment, the mold has a first space 210 overlapping with the bending portion of the display panel DP, a second space 220 overlapping with the driving unit IC, and a third space 230 overlapping with the display panel DP.

In another embodiment, the mold may include only part of the first space 210, the second space 220, and the third space 230.

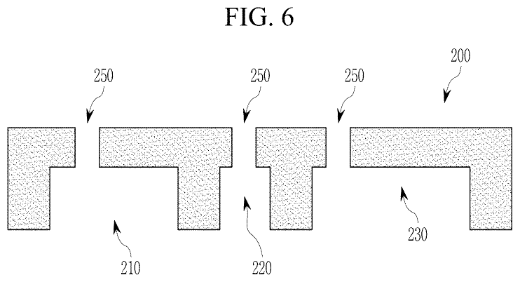

FIG. 6 shows a mold 200, according to an embodiment.

In an embodiment and referring to FIG. 6, the mold 200 includes openings 250 for injection of a resin.

In an embodiment, an opening 250 may be located in each of the first space 210, the second space 220, and the third space 230.

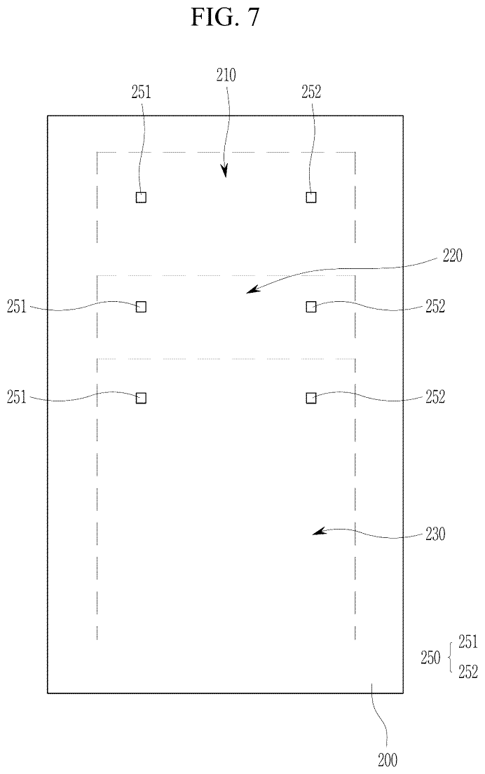

In an embodiment, although only three openings 250 are shown in FIG. 6, referring to FIG. 7, the openings 250 may also include an injection opening 251 and a discharge opening 252.

That is, in an embodiment, each space may include two or more openings 250.

FIG. 7 shows the front of the mold, according to an embodiment.

In an embodiment and referring to FIG. 7, the first space 210, the second space 220, and the third space 230 of the mold 200 may include an injection opening 251 and a discharge opening 252. In each of the first space 210, the second space 220, and the third space 230, the resin is injected through the injection opening 251, and when the resin is sufficiently filled, the remaining resin is discharged through the discharge opening 252.

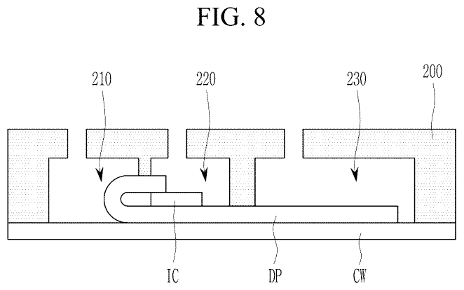

FIG. 8 to FIG. 10 illustrate a method of manufacturing a display device, according to an embodiment.

In an embodiment and referring to FIG. 8, the mold 200 is placed on the back of the display panel DP.

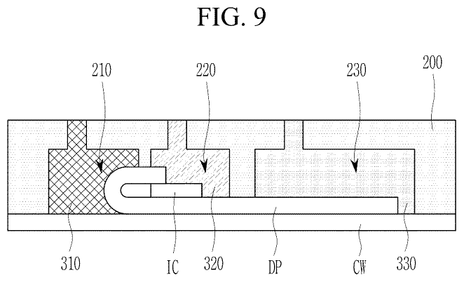

Next, in an embodiment, referring to FIG. 9, the first space 210, the second space 220, and the third space 230 of the mold 200 are filled with a resin.

At this time, in an embodiment, the composition and physical properties of the resin filled in the first space 210, the second space 220, and the third space 230 are the same as those described above and descriptions thereof are omitted.

Detailed descriptions of the same components are omitted.

In an embodiment, through this process, the first resin layer 310, the second resin layer 320, and the third resin layer 330 as described above are formed.

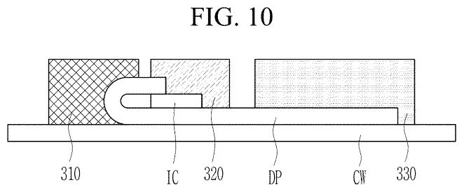

Next, In an embodiment and referring to FIG. 10, the mold 200 is removed.

At this time, in an embodiment, during the removal of the mold, traces of the opening 250 may remain on the surfaces of the first resin layer 310, the second resin layer 320, and the third resin layer 330.

That is, in an embodiment, each of the first resin layer 310, the second resin layer 320, and the third resin layer 330 is disposed within the first space 210, the second space 220, and the third space 230 within the mold 200. It is formed to fill the spaces 210, 220, 230 and the openings 250.

Therefore, in an embodiment, in the removal process of the mold 200, a process of cutting the resin layer filled in the openings 250 is required, and traces of the cut resin layer that filled the openings 250 may remain on the surfaces of the first resin layer 310, the second resin layer 320, and the third resin layer 330.

As described above, in the display device according to an embodiment, resin layers having different physical properties were placed in each region of the display device.

In the existing case, the characteristics required for each area of the display device were different, so it was difficult to delete and integrate individually existing materials, the process cost increased, and there were problems with insufficient characteristics being satisfied.

However, the display device according to an embodiment satisfies the physical properties required for each region by placing a resin layer with different physical properties in each region of the display device, and can replace existing materials, thereby reducing process costs.

In addition, the manufacturing method according to an embodiment can form a plurality of resin layers at once by forming a plurality of spaces in one mold, so the manufacturing process is simple.

In addition, in an embodiment, since the thickness, area, and composition of the resin layer can be freely changed for each space, the resin layer can be appropriately modified according to the characteristics of the display device with a high degree of process freedom.

Although embodiments of the present invention have been described in detail above, the scope of the invention is not limited thereto, and various modifications and improvements made by those skilled in the art using the basic concepts of the invention. Embodiments of the invention disclosed herein and illustrated in the drawings are provided as particular examples for more easily explaining the technical contents according to the invention and helping understand the embodiments of the invention, but they not intended to limit the scope of the invention. Accordingly, the scope of the invention should be interpreted to include, in addition to embodiments disclosed herein, all alterations or modifications derived from the technical ideas of the various embodiments. Moreover, the embodiments or parts of the embodiments may be combined in whole or in part without departing from the scope of the invention.

What is claimed is:

1. A display device, comprising:
a display panel; and
a first resin layer and a second resin layer located on the back of the display panel,
wherein the first resin layer is disposed to overlap a side surface of the display panel,
the second resin layer is disposed to overlap a driving part of the display panel, and wherein
the first resin layer and the second resin layer include different materials.

2. The display device of claim 1, wherein the first resin layer has a Young's modulus in the range of about 0.1 MPa to about 1 GPa.

3. The display device of claim 1, wherein
the first resin layer includes a thermosetting resin or a UV curing resin.

4. The display device of claim 1, wherein
the first resin layer includes one or more of an acrylic resin, an epoxy resin, a silicone resin, and any combination thereof.

5. The display device of claim 1, wherein
the display panel includes a bending portion, and
the first resin layer is positioned to overlap the bending portion.

6. The display device of claim 1, wherein
the second resin layer includes a conductive polymer resin.

7. The display device of claim 1, wherein
the second resin layer includes a polymer having an electrical conductivity of about 100 S/cm² or more.

8. The display device of claim 1, wherein
the second resin layer includes one or more of the compounds represented by following Formulas 1 to 5: 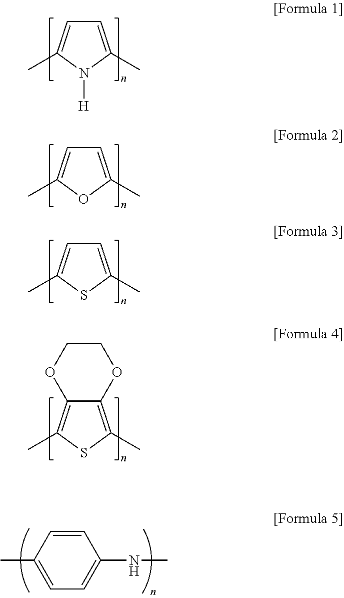
wherein, in the Formulas 1 to 5, n may be in a range of about 10 to about 10,000.

9. The display device of claim 1, wherein
the second resin layer includes a thermally conductive filler.

10. The display device of claim 9, wherein
the content of the thermally conductive filler is in the range of about 0.01 vol % to about 95 vol % based on a total volume of the second resin layer.

11. The display device of claim 1, further comprising
a third resin layer disposed to overlap the display panel.

12. The display device of claim 11, wherein
the third resin layer includes at least one of a thermosetting resin, a UV curing resin, a conductive polymer resin, and a combination thereof.

13. The display device of claim 11, further comprising
a fourth resin layer disposed to overlap the display panel.

14. A method of manufacturing a display device, comprising:
preparing a mold including a first space and a second space, wherein the first space is separated from the second space;
positioning the mold on a display panel back; and
filling the first space with a first resin and filling the second space with a second resin, wherein the second resin includes physical properties different from those of the first resin,
wherein the first space is disposed to overlap a side of the display panel, and
the second space is disposed to overlap a driving part of the display panel.

15. The method of manufacturing a display device of claim 14, wherein
the first resin includes a thermosetting resin or a UV curing resin.

16. The method of manufacturing a display device of claim 14, wherein
the second resin includes a conductive polymer resin.

17. The method of manufacturing a display device of claim 14, wherein
the mold further includes a third space, wherein
the third space is disposed to overlap the display panel.

18. The method of manufacturing a display device of claim 17, further comprising,
filling the third space of the mold with a third resin,
wherein the third resin includes one or more of a thermosetting resin, a UV curing resin, a conductive polymer resin, and a combination thereof.

19. The method of manufacturing a display device of claim 14, wherein
the mold includes openings located in a first space and a second space, and
in the step of filling the first space with the first resin and filling the second space with the second resin, the openings are filled with the first resin and the second resin.

20. The method of manufacturing a display device of claim 19, further comprising
removing the mold, wherein
in the step of removing the mold,
the first resin and the second resin disposed within the openings are cut and removed.
